(19) United States
(12) Patent Application Publication
(10) Pub. No.: US 2018/0231701 A1
(43) Pub. Date: Aug. 16, 2018

(54) SYSTEMS AND METHODS OF PHASE GRATING NANOMANUFACTURING

(71) Applicants: Longfei Ye, Columbia, SC (US); Thomas M. Crawford, Irmo, SC (US); John Tyler Tatum, Atlanta, GA (US); Cameron Nickle, Orlando, FL (US)

(72) Inventors: Longfei Ye, Columbia, SC (US); Thomas M. Crawford, Irmo, SC (US); John Tyler Tatum, Atlanta, GA (US); Cameron Nickle, Orlando, FL (US)

(21) Appl. No.: 15/897,698

(22) Filed: Feb. 15, 2018

Related U.S. Application Data
(60) Provisional application No. 62/459,231, filed on Feb. 15, 2017.

(51) Int. Cl. G02B 5/18; G02B 1/04; H01J 37/305; H01J 37/32

(52) U.S. Cl. CPC G02B 5/1857; G02B 1/04; G02B 6/34; H01J 37/32; H01J 37/3056

(57) ABSTRACT

Disclosed are various embodiments for high diffraction efficiency phase gratings. An organized set of nanoparticles are embedded within a polymer composite. The polymer composite is then etched to generate one or more trenches in the polymer composite that correspond to the organized set of nanoparticles.

### CROSS-REFERENCE TO RELATED APPLICATION

This application claims priority to co-pending U.S. provisional application entitled, “Systems and Methods of Phase Grating Nanomanufacturing,” having application No. 62/459,231, and filed on Feb. 15, 2017, which is entirely incorporated herein by reference.

### BACKGROUND

Originally, fiber optics were primarily used as a backbone technology to increase the capacity of data networks. As the need for data has grown, the demand that fiber optics deliver high volume, high speed capacity has also risen. Further, there is a demand that fiber optics collect data, not just transport it. Fiber to the home and office, fiber as a sensing technology, and the increasing demand for more data are driving fiber optics towards smaller, lower cost devices and components to perform more and more demanding tasks.

In addition, optical sensors, such as, spectrometers and spectroscopies, are used to measure properties of light which can be used to determine characteristics of sample materials. Optical sensors are useful in many applications, including medical, biomedical, astronomy, ecological and chemical applications.

Diffraction gratings are widely used in industry and scientific fields. For example, spectroscopic instruments use diffraction gratings to split the wavelength component of light due to atomic and molecular interactions. In telecommunications, diffraction gratings are used to increase the capacity of fiber-optic networks using the wavelength division multiplexing (WDM).

### SUMMARY

Included are various embodiments of systems and methods related to creating high diffraction efficiency phase gratings.

One embodiment of a method for creating high diffraction efficiency phase gratings, among others, includes embedding an organized set of nanoparticles within a polymer composite and etching the polymer composite to generate one or more trenches in the polymer composite that correspond to the organized set of nanoparticles.

Another embodiment of an apparatus, among others, includes a diffractive optical element, comprising a polymer film comprising a plurality of nanoparticles embedded within the polymer film. The plurality of nanoparticles are organized in a predefined pattern. The diffractive optical element further includes a plurality of trenches disposed about the polymer film. The plurality of trenches correspond to the predefined pattern and the plurality of trenches are disposed in the polymer film via a plasma gas configured to remove portions of the polymer film lacking the plurality of nanoparticles.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout several views.

FIG. 1 illustrates an example of a phase diffraction grating, in accordance with various embodiments of the present disclosure.

FIG. 2 illustrates an example of a scanning electron microscope (SEM) image of an all-nanoparticle grating that is assembled on a perpendicular magnetic medium (e.g., a predefined magnetic fields template) and can be used to create the phase diffraction grating of FIG. 1, in accordance with various embodiments of the present disclosure.

FIG. 3 illustrates an example of a schematic representation of a solid multilayer particle-embedded polymer composite used to generate the phase diffraction grating of FIG. 1, in accordance with various embodiments of the present disclosure.

FIG. 4 illustrates an example of a schematic representation of the fabrication of phase gratings of FIG. 1 by transferring the nanoparticle pattern to the polymer film, in accordance with various embodiments of the present disclosure.

FIG. 5 illustrates an example of a graphical representation of theoretical zero (optical transmission) and first order diffraction efficiencies as a function of ϕ.

FIGS. 6A-6D illustrate examples of assembled nanoparticle lines that are transferred from magnetic recording media onto the surface of a flat glass, in accordance with various embodiments of the present disclosure.

FIG. 7 illustrates an example of a graphical representation of the total diffraction efficiency versus the etching time for a nanomanufactured phase grating according to various embodiments of the present disclosure.

### DETAILED DESCRIPTION

Disclosed herein are various embodiments related to creating high diffraction efficiency phase gratings. The nanomanufacturing process of the present disclosure uses the magnetic moments on a magnetic medium (e.g., hard drive), which traditionally represent stored bits of data, as a template to organize ferrous nanoparticles (e.g., Fe₃O₄, CoFe₂O₄, Co, Ni, Fe and magnetic core/noble metal shell particles such as Fe₃O₄/Au and Fe₃O₄/Cu) into predefined patterned nanoparticle assemblies. These patterns can then be used to create both simple and complex optical designs (e.g., lines, circles, squares, triangles, concentric circles, etc.) for fiber optical systems and optical sensors (e.g., fiber optics and spectrometers). Since the magnetic grains are actually smaller than the nanoparticles, precise control can be exercised over the complex patterns. The high diffraction efficiency phase gratings of the present disclosure can be manufactured using the patterned nanoparticle assemblies and dry etching.

Diffraction gratings are widely used in industry and scientific fields. For example, spectroscopic instruments use diffraction gratings to split the wavelength component of light due to atomic and molecular interactions. In telecommunications, diffraction gratings are being used to increase the capacity of fiber-optic networks using the wavelength division multiplexing (WDM). Diffraction gratings currently available in markets are manufactured using the cleanroom microlithography, originally developed for transistor manufacturing. However, modern integrated circuits require significantly more complicated lithography hardware than are needed for optical components. As such, the embodiments of the present disclosure provide the ability to manufacture high efficiency phase gratings that can reduce the cost of grating-based instruments.

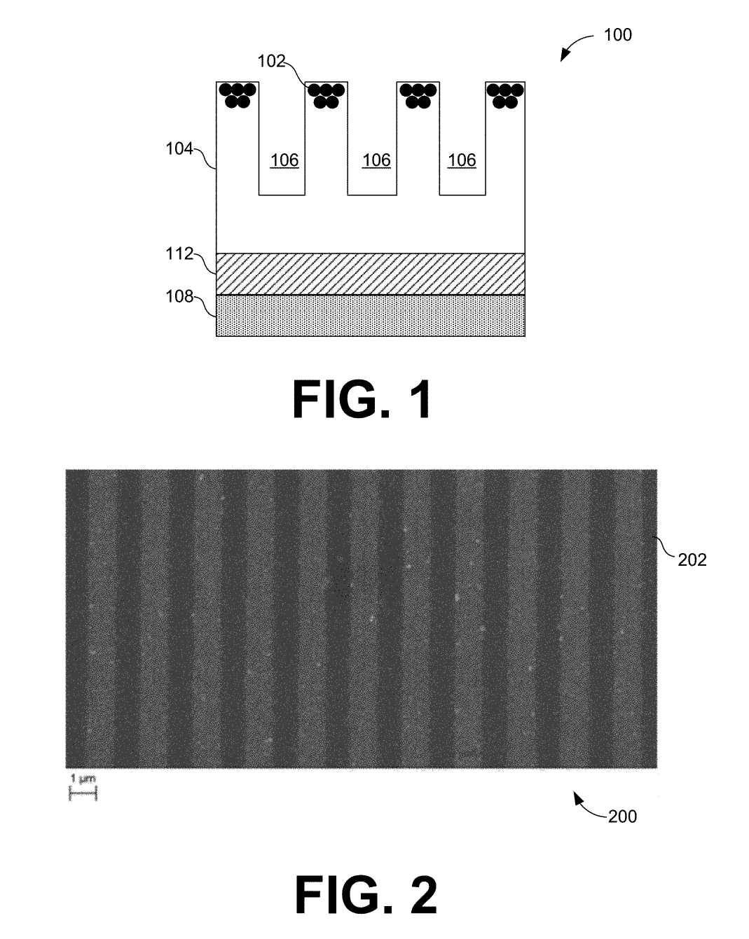

FIG. 1 illustrates an example of a phase diffraction grating 100 according to various embodiments of the present disclosure. The phase diffraction grating 100 comprises organized nanoparticles 102 embedded within a polymer material 104. The polymer material 104 comprises trenches 106 that have been formed according to various embodiments of the present disclosure. The polymer material 104 is affixed to a substrate material 108 via an adhesive material 112. The nanoparticles 102 may comprise Fe₃O₄, CoFe₂O₄, Co, Ni, Fe and magnetic core/noble metal shell particles such as Fe₃O₄/Au and Fe₃O₄/Cu, and/or any other type of nanoparticle as can be appreciated. The polymer material 104 may comprise a polymer such as, for example, polyvinyl alcohol (PVA), poly(methyl methacrylate) (PMMA), polylactic acid (PLLA), and/or any other type of polymer material 104 that can be embedded with the nanoparticles 102 and can be etched, as can be appreciated.

According to various embodiments of the present disclosure, magnetic recording heads can be used to create patterns of nanoparticles 102 on magnetic recording media 202 (FIG. 2). The recorded magnetic medium 202 may be used to assemble the nanoparticles 102 with nanoscale precision into a diffraction grating that has low diffraction efficiencies. The nanoparticle assembly can be transferred to a polymer material 104 (FIG. 1) while preserving the pattern structure to form a particle-embedded polymer composite. In some embodiments, the particle-embedded polymer composite can be removed (e.g., peeled) from the magnetic medium 202 and attached to a substrate material 108. The nanoparticle pattern can then be transferred to the polymer 104 via dry etching, creating phase gratings that have diffraction efficiencies as high as 90%. The substrate material 108 may comprise an end surface of an optical fiber, a gradient-index (GRIN) lens, a glass/Si substrate, curved mirrors/lenses, and/or any other type of substrate as can be appreciated. In some embodiments, the substrate material 108 is flat. In other embodiments, the substrate material 108 is curved.

Known techniques (e.g., lithography, etc.) for creating high diffraction efficiency phase gratings require machines and clean rooms costing several millions to tens of millions of dollars for capital and maintenance cost. Unlike the known techniques, the nanomanufacturing process of the present disclosure does not require a clean room. According to some embodiments of the present disclosure, the optical elements of the present disclosure can be manufactured in a relatively small device, such as, for example, a personal printer.

The methods of the present disclosure can reduce the size, complexity, and cost of fiber optic components. For example, the current optical fiber components can be reduced in size by about 30% to 75%. Additionally, the reduction of cost associated with the manufacturing process of the present disclosure as compared to known techniques is about 10% to 30%. The ability to place a diffractive optic onto the end of a fiber can provide manufacturers with the ability to cost effectively produce products having new functionalities and design products that offer the same functionality with fewer sub-components. WDM multiplexers can increase the efficiencies of fiber optic cables by enabling multiple channels of data to travel through the same cable. This reduces the number of cables needed in a network, thereby reducing costs.

Magnetic field templates that comprise the nanoscale magnetic field patterns on magnetic recording media can be created as described in U.S. Pat. No. 8,617,643, filed Oct. 1, 2007 and entitled “Reprogrammable Parallel Nanomanufacturing” and U.S. Patent Publication No. 2012/0094017, filed Oct. 19, 2011 and entitled: “Patterned Nanoparticle Assembly Methodology,” both of which are hereby incorporated by reference in their entirety.

For example, enormous magnetic field gradients emitting from the template surface exert magnetic forces on nanoparticles 102 that are colloidally suspended in a fluid (e.g., a ferrofluid) deposited on the template surface. These forces assemble the nanoparticles 102 into patterns on the template surface as magnetically programmed. After coating nanoparticles 102 for a period of time (e.g., about 5 min-about 2 hours) depending on the template, nanoparticle and pattern sizes, and subsequently removing the fluid, the patterned particle assembly remains on the template surface. This particle assembly can be transferred from the template surface to an optical transparent polymer, creating all-nanoparticle diffraction gratings, as described in U.S. Publication No. 2014/0307322, filed on Apr. 14, 2014 and entitled “All-Nanoparticle Concave Diffraction Grating Fabricated by Self-Assembly onto Magnetically-Recorded Templates,” which is hereby incorporated by reference in its entirety.

While the all-nanoparticle diffraction gratings are extremely low cost, the commercial use is limited by their low diffraction efficiencies (e.g., typically <10%). This is because assembled nanoparticle patterns are usually thinner than 100 nanometer (nm) due to the field gradients decaying exponentially with distance from the template surface. While the profile of field gradients can be improved to assemble thicker patterns of nanoparticles that can produce larger diffraction efficiency, the embodiments of the present disclosure converts the all-nanoparticle diffraction gratings into phase gratings.

According to various embodiments of the present disclosure, prerecorded magnetic field templates can be used to assemble colloidal nanoparticles into all-nanoparticle diffraction gratings. As described in U.S. Publication No. 2015/0125623, filed on Nov. 7, 2014 and entitled “Patterned Nanoparticle Assembly Methodology,” which is herein incorporated by reference in its entirety, the nanoparticle assembly process is optimized by tuning properties of surrounding fluid, such as, for example, the ionic strength of the fluid, while monitoring optical diffraction as nanoparticles self-assemble in real-time. This ensures an all-nanoparticle grating is assembled with optimal quality. After coating the nanoparticles 102 for a length of time (e.g., about 5 min-about 2 hours), the fluid is removed from the template surface while assembled particles 102 remain.

FIG. 2 illustrates an example of a scanning electron microscope (SEM) image of an all-nanoparticle grating 200 that is assembled on a perpendicular magnetic medium 202, according to various embodiments of the present disclosure. In particular, FIG. 2 shows an example of such all-nanoparticle gratings (˜4% total diffraction efficiency determined using a 632.8 nanometer (nm) laser) that contains one (1) micrometer (μm) wide particle lines with two (2) μm spacing (500 lines/millimeter (mm)), according to various embodiments of the present embodiment. The grating of FIG. 2 is assembled with about thirteen (13) nm diameter Fe₃O₄ (e.g., EMG-707 ferrofluid, Ferrotec, Nashua, N.H.) nanoparticles 102, and has fifty (50) nm thick particle patterns as determined using atomic force microscopy (AFM).

According to various embodiments, a curable polymer 104 can be spin-coated on the medium surface 202, substantially immobilizing the assembled nanoparticles 102 in the polymer film 104. After curing the polymer 104 in air, the particle assembly are embedded in the flexible polymer film 104 while preserving the pattern structure. This creates a standalone particle-embedded polymer composite with the nanoparticles 102 embedded in the polymer film 104.

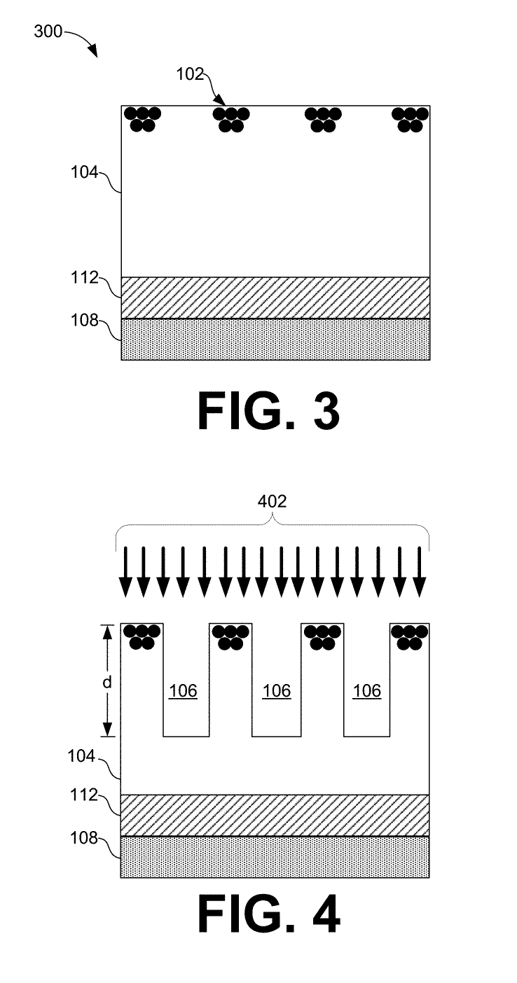

According to various embodiments, the polymer film 104 containing the embedded nanoparticles 102 can be removed from the medium surface 202 and then can be attached to the surface of a substrate material 108 (e.g., a glass slide, an optic fiber, lens, etc.) using an adhesive layer 112 (e.g., curable epoxy or adhesive). FIG. 3 illustrates an example of a schematic representation of a solid multilayer particle-embedded polymer composite 300 according to various embodiments of the present disclosure. As schematically shown in FIG. 3, the polymer material 104 embedded with the nanoparticles 102 is transferred to an adhesive layer 112 disposed on a top surface of the substrate 108 surface. In some embodiments, the adhesive layer 112 is spin-coated on the substrate 108 surface. According to various embodiments, the adhesive layer 112 is optically transparent and ultra-violet (UV) curable. In some embodiments, upon transferring the polymer 104 embedded with the nanoparticles 102 to a top surface of the substrate 108 via the adhesive layer 112, the adhesive layer 112 is UV cured to form the solid multilayer particle-embedded polymer composite 300.

According to various embodiments, pattern transfer techniques can be employed to further transfer the particle pattern to the polymer 104, creating a phase grating 100. The pattern transfer technique may comprise reactive ion etching (RIE), photolithography, and or any other type of technique that can etch the polymer 104 to form the preferred trenches 106.

For example, according to various embodiments, the polymer 104 can be etched using RIE. RIE uses a plasma 402 (FIG. 4) comprising chemically reactive gases in the plasma state to remove materials. Specifically, the plasma 402 comprises a partially ionized gas comprising of equal number of positive ions and negative electrons and a different number of neutral gas molecules. The plasma 402 may comprise oxygen (O₂), tetrafluoromethane (CF₄), (CHF3) argon (Ar), sulfur hexafluoride (SF6), and/or any other type of plasma gas as can be appreciated.

The positive ions of the gas molecules are accelerated to bombard the portions of the polymer 104 to be etched. The plasma ions can react chemically with the polymer 104 and, thus, remove materials of on the surface of the portions of the polymer 104. The nanoparticles 102 block the plasma ions so that only the portions of the polymer 104 that do not include the nanoparticles 102 are etched upon reaction with the plasma ions. The RIE process can be highly anisotropic and selective, and its anisotropy and selectivity can be controlled by selecting RIE gases and tuning the RIE power. Therefore, the RIE can be used to transfer the particle pattern to the polymer by choosing a RIE gas that has a high etching selectivity.

Turning now to FIG. 4, shown is an example of a schematic representation of the fabrication of phase gratings by transferring the nanoparticle pattern to the polymer film 104 using RIE. Specifically, FIG. 4 shows a plasma gas 402 above the solid multilayer particle-embedded polymer composite 300. The positive ions of the plasma gas molecules move downward to react with the surface of the nanoparticles 102 and polymer 104. The etching rate for the polymer 104 should be larger than the etching rate for the nanoparticles 102. For example, the measured etching rate for the polymer 104 comprising PVA is more than five hundred times larger than that for Fe₃O₄ nanoparticles 102, and thus a short duration RIE creates trenches 106 in the polymer 104 since the polymer 104 under the nanoparticles pattern 102 (e.g., a hard mask) is not exposed to energetic chemical ions. The trench width equals the grating period minus the width of particle line. This converts an all-nanoparticle diffraction grating 200 (e.g., patterned particle assembly) into a phase grating 100 with a customizable phase modulation that depends on the trench depth d. As such, the depth d and the time of etching rate can be controlled.

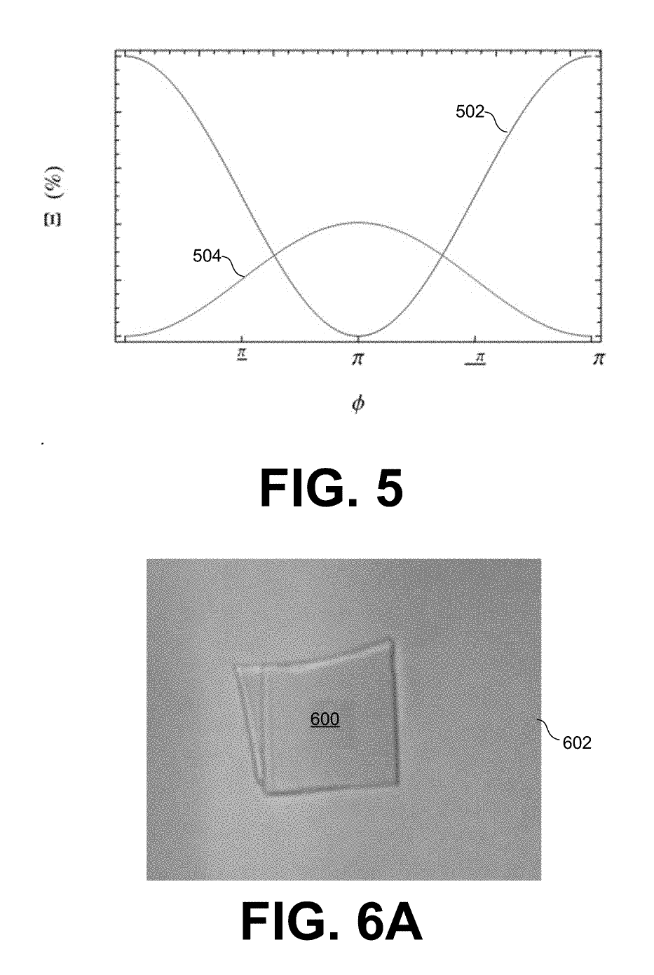

The phase modulation for light incident on the phase grating 100 can be approximately calculated as

$$φ = \frac{2 π ( n - 1 ) d}{λ} \qquad ( Equation 1 )$$

where n is the refractive index of the polymer 104, and λ is the light wavelength. A specific ϕ can be designed to produce phase gratings 100 that have high diffraction efficiencies. For instance, the diffraction efficiency (Ξ) for a 50/50 binary phase grating (e.g., FIG. 5) at normal incidence can be theoretically computed using the Fourier transform for the Fraunhofer diffraction [8] as

$${Ξ}_{m} ( φ ) = \{ \begin{matrix}\frac{1 + cos ( φ )}{2} for m = 0 \\ \frac{1 - cos ( φ )}{2} {sinc}^{2} ( \frac{m}{2} )\end{matrix} \qquad ( Equation 2 )$$

where m is the diffraction order and

$$sinc ( x ) = \frac{sin ( π x )}{π x} .$$

Note Ξ₀+Ξ_{m(m≠}0)=1. FIG. 5 illustrates an example of a graphical representation of theoretical zero (optical transmission) 502 and first order diffraction efficiencies 504 as a function of ϕ. Specifically, FIG. 5 shows the diffraction efficiencies 504 as a function of ϕ for m=±1, together with the optical transmission 502 (i.e., m=0) respectively. A binary phase grating with ϕ=π can produce a diffraction efficiency (Ξ₊₁+Ξ₋₁) as high as 80%.

Efficiency depends on the depth d and the polymer refractive index. As such, the frequency to efficiency can be tuned according to the trench depth d and/or the type of polymer material 104 as the refractive index of different polymers varies.

In other embodiments, alternative methods may comprise transferring patterns of nanoparticles that are assembled on magnetic recording media to the surface of various target substrates such as, for example, glass, Si, and curved lenses. According to various embodiments, the transfer process may allow for patterns of nanoparticles to not be embedded in a polymer. In such embodiments, only the nanoparticles remain on the target substrate. The transferred pattern of nanoparticles can adhere to the surface of target substrates through van der Waals forces.

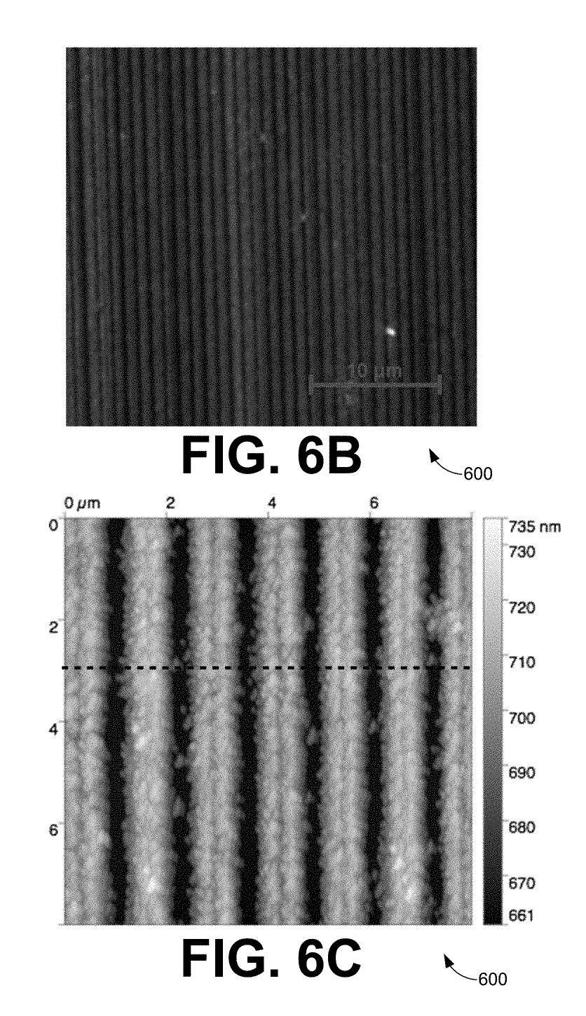

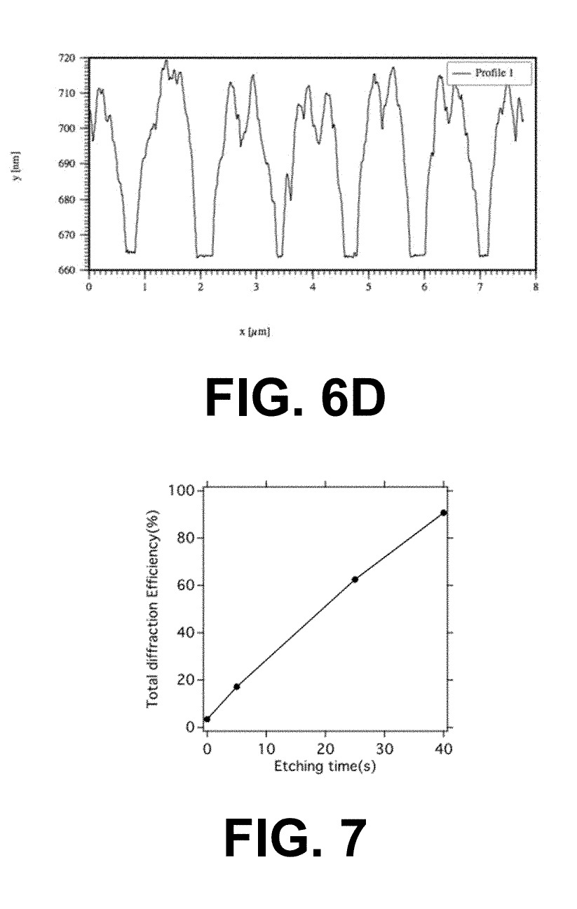

FIG. 6A shows an example of an illustration of nanoparticle lines 600 (an area of 5×5 mm²) that are transferred onto the surface of a flat glass 602. FIGS. 6B and 6C illustrate examples of amplified dark-field and AFM images of the nanoparticle lines 600, according to various embodiments of the present disclosure. The bright lines are patterned nanoparticles and the dark lines are the trenches between nanoparticle lines 600 (i.e., the glass). A linescan of the AFM image, as indicated with the dashed line in FIG. 6C, shows the nanoparticle pattern is about 50 nm thick (see FIG. 6D). This thickness is same as that of the nanoparticle pattern previously assembled on magnetic recording media, demonstrating no polymer exists on top of the transferred patterns or the bottom of trenches. These patterns of nanoparticles that are transferred onto target substrates may be useful for making optics such as, for example, transmission gratings and surface plasmon resonance (SPR) optical sensors.

### Example 1

An all-nanoparticle diffraction grating 200 (1 μm wide and 50 nm thick particle patterns), as shown in FIG. 2, is transferred to a 1.1 μm thick polymer film 104 of Diskcoat 4220. This particle/Diskcoat composite is attached to a five (5) mm diameter and 0.5 mm thick coverslip using a 300 nm thick thin film of Norland optical adhesive (NOA) 86 adhesive. The NOA 86 is UV cured for about ten minutes using a 365 nm UV lamp. An O₂ assisted RIE is used to create the phase grating.

FIG. 7 illustrates an example of a graphical representation of the total diffraction efficiency versus the etching time for a nanomanufactured phase grating according to various embodiments of the present disclosure. The diffraction efficiency is measured with a helium neon (HeNe) laser (e.g., wavelength=632.8 nm). As shown in FIG. 7, the total diffraction efficiency increases dramatically up to 90% for a forty second etching time because the etching depth d and ϕ strongly depend on the etching time.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A method for creating high diffraction efficiency phase gratings, comprising:
embedding an organized set of nanoparticles within a polymer composite; and
etching the polymer composite to generate one or more trenches in the polymer composite that correspond to the organized set of nanoparticles.

2. The method of claim 1, wherein embedding the organized set of nanoparticles within the polymer composite further comprises:
organizing the set of nanoparticles on a magnetic medium;
spin-coating the polymer composite onto the magnetic medium, the organized set of nanoparticles being substantially immobilized in the polymer composite; and
curing the polymer composite.

3. The method of claim 2, further comprising:
removing the polymer composite from the magnetic medium; and
attaching the polymer composite embedded with the organized set of nanoparticles on a glass substrate via an adhesive.

4. The method of claim 1, wherein etching the polymer composite further comprises applying a plasma gas to remove portions of the polymer composite lacking the organized set of nanoparticles.

5. The method of claim 4, wherein one or more portions of the polymer composite situated below the organized set of nanoparticles are not exposed to the plasma gas.

6. The method of claim 4, wherein the plasma gas comprises oxygen.

7. The method of claim 4, wherein the plasma gas comprises tetrafluoromethane.

8. The method of claim 1, wherein the polymer composite is dry-etched via reactive ion etching.

9. The method of claim 1, wherein the one or more trenches of the polymer composite are created via photolithography.

10. The method of claim 1, wherein a phase modulation of the phase gratings is dependent upon a trench depth of the one or more trenches.

11. The method of claim 1, where a diffraction efficiency is dependent upon a trench depth of the one or more trenches.

12. The method of claim 1, wherein the polymer composite comprises at least one of polyvinyl alcohol or poly(methyl methacrylate).

13. The method claim 1, wherein the organized set of nanoparticles comprise Fe₃O₄ nanoparticles.

14. A diffractive optical element, comprising:
a polymer film comprising a plurality of nanoparticles embedded within the polymer film, the plurality of nanoparticles being organized in a predefined pattern; and
a plurality of trenches disposed about the polymer film, the plurality of trenches corresponding to the predefined pattern, the plurality of trenches being disposed in the polymer film via an a plasma gas configured to remove portions of the polymer film lacking the plurality of nanoparticles.

15. The diffractive optical element of claim 14, further comprising a substrate and an adhesive layer, the polymer film being coupled to a top surface of the substrate via the adhesive layer.

16. The diffractive optical element of claim 15, wherein the substrate comprises an optical fiber, a gradient-index lens, or a glass substrate.

17. The diffractive optical element of claim 15, wherein the plurality of nanoparticles are organized in the predefined pattern via a magnetic medium, the plurality of nanoparticles being embedded within the polymer film in response to spin-coating the polymer film on the magnetic medium comprising the plurality of nanoparticles organized in the predefined pattern.

18. The diffractive optical element of claim 14, wherein the polymer film comprises at least one of polyvinyl alcohol or silica.

19. The diffractive optical element of claim 14, wherein the plurality of nanoparticles comprise Fe₃O₄ nanoparticles.

20. The diffractive optical element of claim 14, wherein the plasma gas comprises tetrafluoromethane or oxygen.
